(19) United States
(12) Patent Application Publication
(10) Pub. No.: US 2026/0202485 A1
(43) Pub. Date: Jul. 16, 2026

(54) INFORMATION PROCESSING SYSTEM, INFORMATION PROCESSING METHOD, AND INFORMATION PROCESSING PROGRAM

(71) Applicant: KABUSHIKI KAISHA TOYOTA CHUO KENKYUSHO, Nagakute-shi, Aichi-ken (JP)

(72) Inventors: Kazuya SHITAOKA, Nagakute-shi (JP); Hiroki KONDO, Nagakute-shi (JP); Tsuyoshi SASAKI, Nagakute-shi (JP)

(73) Assignee: KABUSHIKI KAISHA TOYOTA CHUO KENKYUSHO, Nagakute-shi, Aichi-ken (JP)

(21) Appl. No.: 19/135,252

(22) PCT Filed: Oct. 26, 2023
(86) PCT No.: PCT/JP2023/038616

§ 371 Date: Jun. 3, 2025

(30) Foreign Application Priority Data
Feb. 9, 2023 (JP) 2023-018076

(51) Int. Cl. G01R 31/392

(52) U.S. Cl. CPC G01R 31/392

(57) ABSTRACT

An information processing system, including at least one processor configured to execute a program so as to execute each step of: an acquisition step of acquiring a test condition of a first deterioration test performed on a secondary battery and a test result from the first deterioration test, a rate calculation step of calculating a capacity deterioration rate of the secondary battery under the test condition based on the capacity deterioration amount; an estimation step of estimating, based on the calculated capacity deterioration rate, a capacity deterioration rate of the secondary battery under at least one of untested conditions; a map generation step of generating a deterioration rate map; a priority calculation step of calculating priority of each of the untested conditions for performing a second deterioration test; and a candidate output step of outputting a candidate for the second deterioration test.

### BACKGROUND

The present disclosure relates to an information processing system, an information processing method, and an information processing program.

### RELATED ART

Patent document 1 discloses a storage battery diagnostic apparatus that aims to inform the state of deterioration of a storage battery while performing charging and discharging with a simple configuration.

This storage battery diagnostic apparatus includes a SOC acquisition unit that acquires a SOC of a storage battery, a temperature acquisition unit that acquires the temperature of the storage battery, a storage unit that stores a deterioration rate characteristic indicating a relationship between the temperature and SOC of the storage battery and the deterioration rate, a diagnosis unit that specifies the deterioration rate of the storage battery based on the acquired temperature and SOC and the deterioration rate characteristic and calculates a deterioration degree of the storage battery by accumulating the deterioration rate over a predetermined period, and an output unit that outputs information related to the deterioration state of the storage battery based on the deterioration degree.

### PRIOR ART DOCUMENTS

### Patent Document

[Patent Document 1] JP 2020-38138 A

### SUMMARY

### Problems to be Solved by Invention

However, the technology disclosed in Patent Document 1 may require high costs for testing the storage battery, which is necessary when generating the deterioration rate characteristics.

### Means for Solving Problems

According to an aspect of the present disclosure, an information processing system is provided. This information processing system includes at least one processor configured to execute a program so as to execute the following steps. In an acquisition step, a test condition of a first deterioration test performed on a secondary battery and a test result from the first deterioration test are acquired. The test condition includes a test time for performing the first deterioration test. The test result includes a capacity deterioration amount of the secondary battery. In a rate calculation step, a capacity deterioration rate of the secondary battery under the test condition is calculated based on the capacity deterioration amount. In an estimation step, a capacity deterioration rate of the secondary battery under at least one of untested conditions representing test conditions that have not been acquired is estimated based on the calculated capacity deterioration rate. In a map generation step, a deterioration rate map that indicates a correspondence relation between the test condition and the capacity deterioration rate is generated based on the calculated capacity deterioration rate and the estimated capacity deterioration rate. In a priority calculation step, priority of each of the untested conditions for performing a second deterioration test is calculated based on the generated deterioration rate map. In a candidate output step, a candidate for the second deterioration test in which at least one of the untested conditions is a test condition is output based on the calculated priority, in a manner selectable by a user.

According to this configuration, a deterioration rate map can be obtained while reducing test costs compared to conventional test methods.

### BRIEF DESCRIPTION OF DRAWINGS

FIG. 1 is a configuration diagram representing an information processing system 1.

FIG. 2 is a block diagram showing a hardware configuration of an information processing apparatus 2.

FIG. 3 is a block diagram showing a hardware configuration of a user terminal 3.

FIG. 4 shows an example of a configuration of a deterioration testing apparatus 4.

FIG. 5 shows an example of functional units included in a processor 23.

FIG. 6 is a flowchart showing an overview of a flow of information processing executed in the information processing system 1.

FIG. 7 is a flowchart showing a flow of search processing.

FIG. 8 is a flowchart showing a flow of correction processing.

FIG. 9 shows an example of estimation results of the time dependence of a capacity deterioration amount ΔC.

### DETAILED DESCRIPTION

Hereinafter, an embodiment of the present disclosure will be described with reference to drawings. Various features described in the embodiment below can be combined with each other.

A program for realizing a software in the present embodiment may be provided as a non-transitory computer readable storage medium, may be provided for download from an external server, or may be provided in such a manner that the program can be activated on an external computer to realize functions thereof on a client terminal (so-called cloud computing).

A term “unit” in the present embodiment may include, for example, a combination of a hardware resource implemented as circuits in a broad sense and information processing of software that can be concretely realized by the hardware resource. Furthermore, various kinds of information are described in the present embodiment, and such information may be represented by, for example, physical values of signal values representing voltage and current, high and low signal values as a set of binary bits consisting of 0 or 1, or quantum superposition (so-called qubits), and communication and computation may be executed on a circuit in a broad sense.

The circuit in a broad sense is a circuit realized by properly combining at least a circuit, circuitry, a processor, a memory, and the like. In other words, a circuit includes an application specific integrated circuit (ASIC), a programmable logic device (e.g., simple programmable logic device (SPLD), a complex programmable logic device (CLPD), field programmable gate array (FPGA), and the like.

### 1. Hardware Configuration

This section describes a hardware configuration.

### <Information Processing System 1>

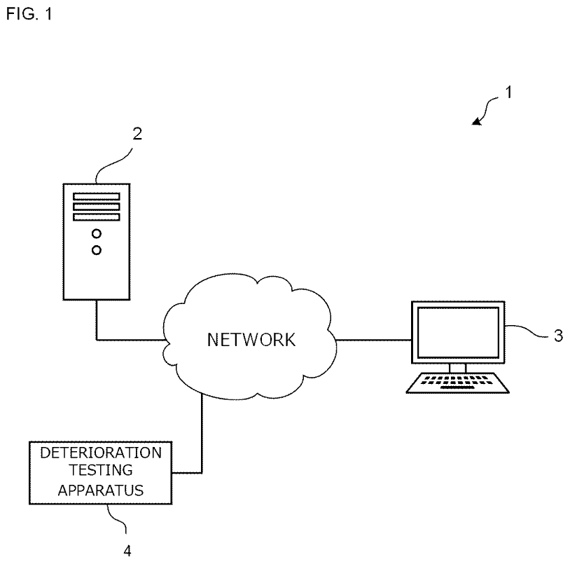

FIG. 1 is a configuration diagram representing an information processing system 1. The information processing system 1 includes an information processing apparatus 2, a user terminal 3, and a deterioration testing apparatus 4. The information processing apparatus 2, the user terminal 3, and the deterioration testing apparatus 4 are configured to be able to communicate via a telecommunication line. In one embodiment, the information processing system 1 is composed mainly of one or more devices or components. If, for example, the information processing system 1 is composed only of the information processing apparatus 2, the information processing system 1 can be the information processing apparatus 2. Hereinafter, explanation of these components will be provided.

### <Information Processing Apparatus 2>

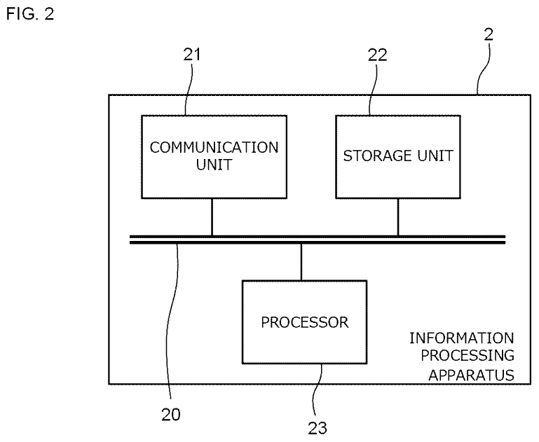

FIG. 2 is a block diagram showing a hardware configuration of the information processing apparatus 2. The information processing apparatus 2 includes a communication unit 21, a storage unit 22, and a processor 23, and these components are electrically connected via a communication bus 20 inside the information processing apparatus 2. Each of the components will be further described below.

The communication unit 21 is preferably a wire communication means such as USB, IEEE1394, Thunderbolt (registered trademark), wired LAN network communication, etc., but may also include wireless LAN network communication, mobile communication such as 3G/LTE/5G, Bluetooth (registered trademark) communication, and the like as necessary. More preferably, integration of these plural communication means is used. That is, the information processing apparatus 2 may communicate various kinds of information from outside via the communication unit 21 and a network.

The storage unit 22 stores various kinds of information defined by the above description. This is, for example, the storage unit 22 can store such information as a storage device such as a solid state drive (SSD) that stores various programs, etc. related to the information processing apparatus 2, which are executed by the processor 23, or as a memory such as a random access memory (RAM) that stores temporarily necessary information (arguments, arrays, etc.) for program calculations. The storage unit 22 stores various programs and variables related to the information processing apparatus 2, which are executed by the processor 23.

The processor 23 processes and controls overall operations related to the information processing apparatus 2. The processor 23 is, for example, an unshown central processing unit (CPU). The processor 23 reads out a predetermined program stored in the storage unit 22 so as to realize various functions related to the information processing apparatus 2. That is, the information processing by software stored in the storage unit 22 is specifically realized by the processor 23 as an example of hardware, and can be executed by each functional unit included in the processor 23. They will be described in more detail in a next section. Incidentally, the processor 23 is not limited to be single, but may be implemented so as to include a plurality of the processors 23 for each function. Also, the processor 23 may be a combination of the structures described above . . . .

### <User Terminal 3>

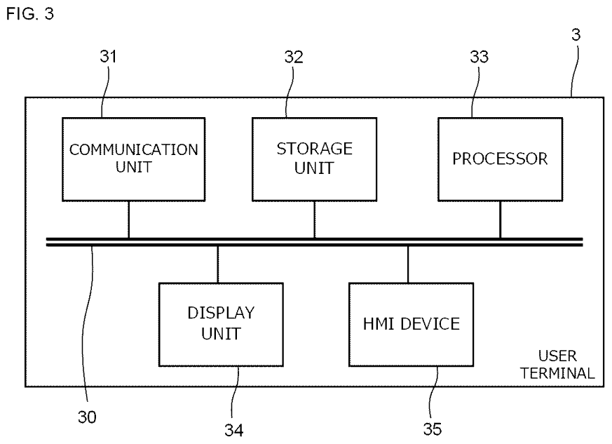

FIG. 3 is a block diagram showing a hardware configuration of the user terminal 3. The user terminal 3 includes a communication unit 31, a storage unit 32, a processor 33, a display unit 34, and an HMI device 35, and these components are electrically connected via a communication bus 30 inside the user terminal 3. Descriptions of the communication unit 31, the storage unit 32 and the processor 33 are the same as those of the respective units in the information processing apparatus 2, and are therefore omitted.

The display unit 34 may be included in a housing of the user terminal 3, or may be attached thereto externally. The display unit 34 displays a screen of a graphical user interface (GUI) that can be operated by a user. This should be implemented, for example, by using different display devices such as a CRT display, a liquid crystal display, an organic EL display, and a plasma display, depending on the type of the user terminal 3.

The HMI device 35 is a Human-Machine Interface device. The HMI device 35 may be included in a housing of the user terminal 3, or may be attached thereto externally. For example, the HMI device 35 may be integrated with the display unit 34 and implemented as a touch panel. With a touch panel, the user can input tap operations, swipe operations, etc. Of course, a switch button, mouse, QWERTY keyboard, a voice recognition device, a gesture detection device, a gaze detection device, an eye tracking device, a biometric signal detection device, an imaging device, etc. may be employed instead of a touch panel. In other words, the HMI device 35 receives operation inputs made by the user. In response, the HMI device 35 transfers a signal corresponding to the operation input to the processor 33 via the communication bus 30. The processor 33 can execute predetermined control or arithmetic operations as necessary. The HMI device 35 can be said to include an input unit configured to receive input from the user.

### <Deterioration Testing Apparatus 4>

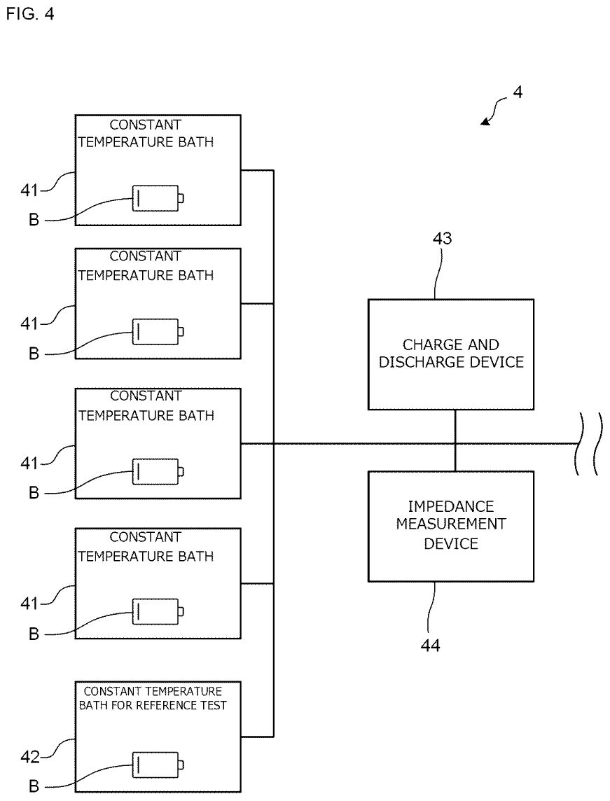

FIG. 4 shows an example of a configuration of a deterioration testing apparatus 4. The deterioration testing apparatus 4 includes at least one constant temperature bath 41, one reference constant temperature bath 42, a charge and discharge device 43, and an impedance measurement device 44, and these components are configured to be able to communicate with each other.

Each of the constant temperature bath 41 and the reference constant temperature bath 42 is configured to accommodate a secondary battery B therein. The constant temperature bath 41 is configured to perform a deterioration test on the secondary battery B. The reference constant temperature bath 42 is configured to perform, for example, a deterioration test on the secondary battery B, similarly to the constant temperature bath 41. The reference constant temperature bath 42 is configured to perform a deterioration test on the secondary battery B based on the initial test conditions described below. The secondary battery B may be any battery as long as it is configured to perform charging and discharging, such as a lead-acid battery, nickel-cadmium storage battery, lithium-ion storage battery, air battery, etc.

The charge and discharge device 43 is configured to perform a deterioration test on the secondary battery B by controlling the operations of the constant temperature bath 41, the reference constant temperature bath 42, and the secondary battery B. The charge and discharge device 43 is configured, for example, to control the temperature of the constant temperature bath 41 and the reference constant temperature bath 42 in accordance with the test conditions of the deterioration test. The charge and discharge device 43 is also configured to control the charge and discharge of the secondary battery B, e.g., the charge and discharge rate of the secondary battery B and the voltage and current during the charge and discharge, in accordance with the test conditions.

The impedance measurement device 44 is configured to measure impedance and open circuit voltage (OCV) of the secondary battery B along with the control of the secondary battery B by the charge and discharge device 43.

The test conditions of the present embodiment include a test time for performing a first deterioration test, the temperature of the constant temperature bath 41 (in other words, the temperature of the secondary battery B), the current rate of the secondary battery B, the average SOC (State of Charge), and the SOC range. These elements that define test conditions are used as elements of the state space that represent the test conditions when generating a deterioration rate map described below. The test conditions may include elements other than those described above as elements of such state space. For example, the test conditions may include a temperature adjustment rate, and a temperature adjustment time of the constant temperature bath 41, etc., and a waiting time after the target SOC is reached.

The test conditions are set within a preset test range. The test range includes, for example, the temperature range of the constant temperature bath 41, the range of the current rate of the secondary battery B, the range of the average SOC, the value of the SOC range, and the like.

### Functional Configuration of Information Processing Apparatus 2

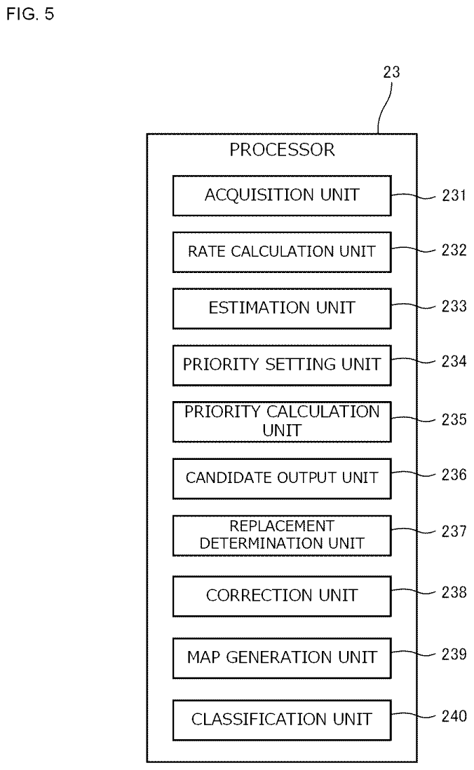

FIG. 5 shows an example of functional units included in the processor 23. As shown in FIG. 5, the processor 23 includes an acquisition unit 231, a rate calculation unit 232, an estimation unit 233, a priority setting unit 234, a priority calculation unit 235, a candidate output unit 236, a replacement determination unit 237, a correction unit 238 and a map generation unit 239. This section describes an overview of these functional units. The details of each functional unit will be described in conjunction with the information processing described later.

The acquisition unit 231 is configured to acquire information from the user terminal 3, the deterioration testing apparatus 4 or other devices. The acquisition unit 231 is configured to acquire various kinds of information by reading out various kinds of information stored in a storage area that is at least a part of the storage unit 22 and writing the read out information into a work area that is at least a part of the storage unit 22. The storage area is, for example, an area of the storage unit 22 that is implemented as a storage device such as SSD. The work area is, for example, an area that is implemented as a memory, such as RAM, for example. Note that the acquisition by the acquisition unit 231 includes acquiring output results of each functional unit included in the processor 23.

The rate calculation unit 232 is configured to calculate various kinds of information such as a capacity deterioration rate V based on an acquisition result by the acquisition unit 231. The capacity deterioration rate V represents a deterioration amount per unit time of the battery capacity C of the secondary battery B in a given environment.

The estimation unit 233 is configured to estimate various kinds of information such as the capacity deterioration rate V under a certain test condition based on various kinds of information such as the acquisition results of the acquisition unit 231 and the calculation results of the rate calculation unit 232.

The priority setting unit 234 is configured to set priority of the test conditions of a deterioration test to be performed on the secondary battery B, based on various kinds of information and user operations.

The priority calculation unit 235 is configured to calculate priority corresponding to each of the test conditions based on various kinds of information such as the priority set by the priority setting unit 234. Details of the priority will be described later.

The candidate output unit 236 is configured to output various kinds of information such as candidates for test conditions of the deterioration test to be performed on each secondary battery B. The information can be presented to the user via the display unit 34 of the user terminal 3 or other devices. In such a case, for example, the candidate output unit 236 controls the display unit 34 of the user terminal 3 to display visual information such as screens, images including still or moving images, icons, messages and the like. The candidate output unit 236 may generate only rendering information for displaying the visual information on the user terminal 3. The candidate output unit 236 may show the output information to the user not via the user terminal 3 or any other device users.

The replacement determination unit 237 is configured to execute a determination as to whether or not the secondary battery B on which a deterioration test is to be performed based on various kinds of information needs to be replaced.

The correction unit 238 is configured to correct the estimation result, etc. performed by the estimation unit 233 based on various kinds of information.

The map generation unit 239 is configured to generate a deterioration rate map that represents the correspondence relation between the deterioration rate of the secondary battery B and the test conditions based on the calculation results of the rate calculation unit 232, the estimation results of the estimation unit 233, the correction results of the correction unit 238, etc. Updating the deterioration rate map is one aspect of generating the deterioration rate map.

The classification unit 240 is configured to classify test conditions based on various kinds of information.

### 3. Information Processing

This section describes the information processing to be executed in the information processing system 1 described above.

### 3.1. Flow of Information Processing

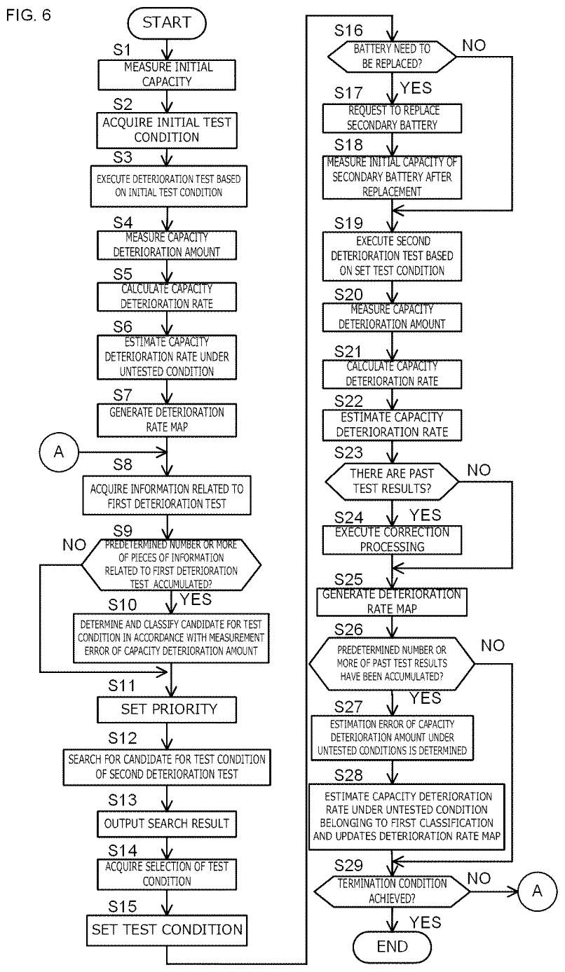

FIG. 6 is a flowchart showing an overview of a flow of information processing executed in the information processing system 1. It should be noted that the information processing may include any exception processing not shown. The exception processing includes interruption of the information processing or omission of each processing. Selection or input performed in the information processing may be based on operations by the user, or may be automatic not by the user's operations.

### [Step S1]

First, the processing proceeds to Step S1, where the processor 23 measures each initial capacity C_ini of the secondary batteries B housed in each of the constant temperature baths 41 and the reference constant temperature bath 42 in advance. These secondary batteries B have never been subjected to a deterioration test in the past. For example, the processor 23 first controls the constant temperature bath 41 and the reference constant temperature bath 42 to make the temperature of each secondary battery B reach a predetermined set temperature. Next, the processor 23 sets a current value used for the charge and discharge of the secondary battery B based on the nominal capacity C_nominal of the secondary battery B. Next, the processor 23 performs constant current constant voltage charging at the set current value until the SOC reaches 100% and constant current constant voltage discharging until the SOC reaches 0%, and the discharge capacity at that time is defined as the initial capacity C_ini.

### [Step S2]

Next, the processing proceeds to Step S2, where the processor 23, functioning as the acquisition unit 231, acquires a preset initial test condition. The initial test condition is a test condition of the first deterioration test. Hereinafter, for convenience of explanation, the deterioration test that has been performed previously is referred to as a first deterioration test, and the deterioration test to be performed next is referred to as a second deterioration test. The initial test described above is an example of the first deterioration test. The first deterioration test can also be said to be a deterioration test that has been performed in the past.

### [Step S3]

Next, the processing proceeds to Step S3, where the processor 23 executes a deterioration test based on the acquired initial test condition. The test results of the executed deterioration test and the test conditions thereof are stored in, for example, the storage unit 22.

### [Step S4]

Next, the processing proceeds to Step S4, where the processor 23 measures a capacity deterioration amount ΔC of each secondary battery B by the deterioration test in Step S3. The measurement method is arbitrary, but for example, the processor 23 measures the battery capacity C after the deterioration test in the same manner as the initial capacity C_ini, and measures the capacity deterioration amount ΔC by subtracting the battery capacity C from the initial capacity C_ini. The measurement of the battery capacity C and the capacity deterioration amount ΔC of the secondary battery B is not limited to being performed directly by the processor 23. For example, the processor 23 may control the deterioration testing apparatus 4 so that the charge and discharge device 43 and the impedance measurement device 44 measure the battery capacity C and the like, and acquire the measurement results output from the deterioration testing apparatus 4.

### [Step S5]

Next, the processing proceeds to Step S5, where the processor 23, functioning as the rate calculation unit 232, calculates the capacity deterioration rate V of each secondary battery B based on the initial test condition and the capacity deterioration amount ΔC.

### [Step S6]

Next, the processing proceeds to Step S6, where the processor 23, functioning as the estimation unit 233, estimates the capacity deterioration rate V under untested conditions based on the calculated capacity deterioration rate V. The untested conditions represent test conditions that have not been previously acquired in this information processing, and are, for example, test conditions for which the test results have not been stored in the storage unit 22 or the like. The method of estimating the capacity deterioration rate V under untested conditions is arbitrary. However, for example, the processor 23 generates and updates a trained model representing a predetermined physical model of the secondary battery B by performing machine learning using the calculated capacity deterioration rate V as learning data. The trained model is configured to output parameters related to the secondary battery B, such as the capacity deterioration rate V, by inputting test conditions. The processor 23 inputs untested conditions to such a trained model, thereby estimating the capacity deterioration rate V under the untested conditions. The specific aspects of generating and updating the trained model are arbitrary, and examples include linear regression, ridge regression, Gaussian process regression, neural networks, and support vector machines. For example, a method of estimating the capacity deterioration rate V using Gaussian process regression include those disclosed in the non-patent document such as “J. Wang, D. Fleet, and A. Hertzmann, “Gaussian Process Dynamical Models”, NIPS 2005”. The processor 23 may estimate the capacity deterioration rate V under the untested conditions based on the calculated capacity deterioration rate V, by using a statistical method based on the aforementioned regression analysis, without using machine learning or the like.

### [Step S7]

Next, the processing proceeds to Step S7, where the processor 23, functioning as the map generation unit 239, generates a deterioration rate map M based on the test condition and the capacity deterioration rate V corresponding to the test condition. The deterioration rate map M indicates a correspondence relation between the test condition and the capacity deterioration rate V. The deterioration rate map M may be expressed in any format, such as a function, a look-up table, or a trained model. In the case where an existing deterioration rate map M exists, the processor 23 may update the existing deterioration rate map M with the generated deterioration rate map M.

### [Step S8]

Next, the processing proceeds to Step S8, where the processor 23, functioning as the acquisition unit 231, acquires information related to the first deterioration test by referring to the storage unit 22 or the like. For example, the processor 23, functioning as the acquisition unit 231, acquires the test conditions of the first deterioration test performed on the secondary battery B and the test results from the first deterioration test. In detail, the processor 23 acquires the test conditions of a plurality of first deterioration tests performed on each of the plurality of secondary batteries B and the capacity deterioration amount ΔC of each of the secondary batteries obtained from each of the plurality of first deterioration tests. In the present embodiment, in addition to the test conditions and test results of the most recent first deterioration test, the processor 23 further acquires the history of the first deterioration test performed on the secondary battery B. The history of the first deterioration test includes test conditions and test results of the plurality of the first deterioration tests that have been performed in the past.

### [Step S9]

Next, the processing proceeds to step S9, where the processor 23 determines whether or not a predetermined number or more of pieces of information related to the first deterioration test has been accumulated, based on the acquired test conditions and test results of the first deterioration test. For example, in the case where any processing included in the present information processing has been performed a predetermined number of times or more for one secondary battery B, the processor 23 determines that a predetermined number or more of past test results have been accumulated. The predetermined number can be set arbitrarily depending on the accuracy of the information related to the measurement error, and is two or more, and more preferably three or more.

### [Step S10]

In the case where it is determined that a predetermined number or more of past test results have been accumulated, the processing proceeds to Step S10, and the processor 23, functioning as the classification unit 240, classifies candidates for the test conditions of the second deterioration test in accordance with the measurement error of the capacity deterioration amount ΔC.

Here, an example of the processing of Step S10 will be described. First, the processor 23 performs a determination related to the measurement error of the capacity deterioration amount ΔC for each test condition. As a result, the processor 23 classifies the test conditions into a test condition belonging to a first classification that indicates a relatively large measurement error among the test conditions within the search range, and a test condition belonging to a second classification that indicates a relatively small measurement error among the test conditions within the search range. For example, the processor 23 executes this determination based on (1) whether or not the estimation result of the current capacity deterioration rate V is less than or equal to the average value of the estimation results of the capacity deterioration rate V under all test conditions, and (2) whether or not the absolute value of the difference between the estimation result of the current capacity deterioration rate V and the estimation result of the previous capacity deterioration rate V under the target test conditions is less than or equal to a predetermined multiple (greater than 0 and less than 1) of the estimation result of the current capacity deterioration rate V. The processor 23 determines that the test condition satisfying both the conditions (1) and (2) is a test condition belonging to the first classification and classifies them accordingly. On the other hand, the processor 23 determines that the test condition that does not satisfy at least one of the conditions (1) and (2) is a test condition belonging to the second classification and classifies them accordingly. (1) is a condition that indicates whether or not the test condition is such that the relative measurement error of the capacity deterioration amount ΔC is large. This is a condition based on the idea that the measurement error of the battery capacity occurs at a constant level regardless of the magnitude of the deterioration amount. (2) is a condition that indicates whether or not the estimation result of the capacity deterioration rate V under the test condition has small variations relative to the past estimation results, thereby indicating the stability of the estimation results.

The processor 23 may also extract test conditions in which the temperature, the average SOC, and the SOC range are common, and classify the extracted test conditions based on a specific test condition which is one of the extracted test conditions. For example, the processor 23 treats a test condition with a relatively high current rate (specifically, the highest one) among the extracted test conditions as a specific test condition. Then, when the processor 23, functioning as the classification unit 240, classifies the specific test condition into the first classification, a test condition with a lower current rate than the specific test condition (in this case, all the extracted test conditions) among the extracted test conditions is classified into the first classification in the same matter as the specific test condition. At this time, even if some of the extracted test conditions are not classified into the first classification, the processor 23 classifies those among the extracted test conditions that satisfy the above conditions into the first classification. This is because the capacity deterioration rate V increases monotonically with respect to the current rate regardless of the type of the secondary battery B. In other words, the capacity deterioration rate V tends to be smaller as the current rate is smaller. This can reduce the load of the classification processing.

### [Step S11]

After Step S10, the processing proceeds to Step S11. On the other hand, in the case where it is determined that the predetermined number or more of past test results have not been accumulated, the processing of Step S10 is skipped and the processing proceeds to Step S11. In Step S11, the processor 23, functioning as the priority setting unit 234, sets priority. The priority functions as an index when searching for candidates for the test condition of the second deterioration test described below. The priority is defined by at least one parameter that represents the advantage or disadvantage of the second deterioration test, such as the reliability of the deterioration rate map M obtained by performing the second deterioration test on the secondary battery B or the cost of performing the second deterioration test. The priority in the present embodiment is defined at least by the standard deviation of the capacity deterioration rate V estimated by the estimation unit 233, the slope of the capacity deterioration rate V in the deterioration rate map M, and the reciprocal of the capacity deterioration rate V. For example, the priority is defined by a weighted linear sum of these parameters. The processor 23 standardizes these parameters so that they can be compared with each other, for example, by processing these parameters so that each takes a value between 0 and 1. Hereinafter, for convenience of explanation, “the slope of the capacity deterioration rate V in the deterioration rate map M” is simply referred to as “the slope of the capacity deterioration rate V”. The slope of the capacity deterioration rate V can be considered, in the extreme case, as the derivative (or gradient) of the capacity deterioration rate V with respect to a parameter representing a certain test condition. The slope of the capacity deterioration rate V may be expressed by a scalar quantity, a vector quantity such as a gradient vector, or by a higher-order tensor quantity.

The standard deviation of the capacity deterioration rate V represents the reliability of the estimation result of the capacity deterioration rate V under the test condition. As this value increases, it suggests that the reliability of the estimation result of the capacity deterioration rate V under the test condition decreases. Thus, the lower the reliability of the estimation result of the capacity deterioration rate V under test conditions, the more preferable it is to calculate the capacity deterioration rate V through a deterioration test. Accordingly, the priority is set to be higher as the standard deviation of the capacity deterioration rate V becomes larger. In other words, the standard deviation of the capacity deterioration rate V is one of the statistics of the capacity deterioration rate V and is one of the parameters that represent the reliability of the deterioration rate map M obtained by performing the second deterioration test on the secondary battery B.

The slope of the capacity deterioration rate V represents the degree of change in the deterioration rate around the test conditions. As this value increases, the accuracy of the estimation result of the capacity deterioration rate V around the test conditions tends to decrease. Thus, the slope of the capacity deterioration rate V is one of the parameters representing the reliability of the deterioration rate map M obtained by performing the second deterioration test on the secondary battery B. Under test conditions where the slope of the capacity deterioration rate V is large, the deterioration tests can be performed to enrich the calculation results of the capacity deterioration rate V and efficiently improve the estimation accuracy of the deterioration rate map M. Thus, the priority is set to be higher as the slope of the capacity deterioration rate V becomes larger. Calculating the standard deviation and slope of the capacity deterioration rate V based on the capacity deterioration amount ΔC of the first deterioration test is one aspect of acquiring the reliability of the generated deterioration rate map M. Thus, the reliability of the deterioration rate map M is calculated based on at least one of the statistics of the calculated capacity deterioration rate V and the slope of the calculated capacity deterioration rate V with respect to the parameters related to the test conditions of the deterioration rate map M.

The reciprocal of the capacity deterioration rate V represents the smallness of the load on the secondary battery B by the deterioration test, and is one of the indices representing the cost of performing the second deterioration test. The larger the value of the reciprocal of the capacity deterioration rate V, the smaller the capacity deterioration amount ΔC during a fixed test time in the deterioration test. Consequently, the larger this value is, the smaller the load on the secondary battery B due to the corresponding deterioration test, making it easier to perform more deterioration tests on one secondary battery B.

The correspondence relation between the priority and these parameters is defined by a priority correspondence relation. The priority correspondence relation in the present t embodiment indicates the correspondence relation of the priority to the reliability of the deterioration rate map M by performing a second deterioration test on the secondary battery B and the cost of performing the second deterioration test, and is defined, for example, by the weight (in other words, coefficient) of each parameter in the linear sum included in the priority.

In the present embodiment, the processor 23, functioning as the priority setting unit 234, sets a priority correspondence relation based on designation by a user. For example, the user specifies a weight of each parameter included in the priority via an input to the HMI device 35. The processor 23 updates the weights for respective parameters included in the priority correspondence relation so that they match the specified weights, and sets the priority based on the updated parameters. The processor 23, functioning as the priority calculation unit 235, calculates the priority based on the set priority correspondence relation.

### [Step S12]

Next, the processing proceeds to Step S12, where the processor 23 calculates the priority corresponding to the test condition only within the search range based on the set priority, and searches for candidates for the test conditions of the second deterioration test to be performed next for each secondary battery B based on the calculated priority. Hereinafter, for convenience of explanation, the processing of searching for such candidates is simply referred to as search processing. In other words, the processor 23, functioning as the priority calculation unit 235, calculates, based on the generated deterioration rate map M, the priority of each of the untested conditions for performing the second deterioration test. In the present embodiment, the processor 23 calculates the priority of each of the untested conditions for performing the second deterioration test based on at least one of the reliability of the deterioration rate map M obtained by further performing the second deterioration test on the secondary battery B under at least one untested condition and the cost of performing the second deterioration test. In Step S10, in the case where the test conditions of the second deterioration test are classified, the search range is limited to the test condition that belongs to one of the classifications. In the present embodiment, the test condition classified as having a relatively small measurement error is set as a search range.

### [Step S13]

Next, the processing proceeds to Step S13, where the processor 23, functioning as the candidate output unit 236, outputs the search results from Step S10. As a result, the processor 23 outputs, based on the calculated priority, candidates for the second deterioration test in which at least one of the untested conditions is a test condition, in a manner selectable by the user. In the present embodiment, the output candidates for the second deterioration test are presented to the user via the display unit 34. The user can select a candidate for the second candidate deterioration test displayed on the display unit 34 through an operation on the HMI device 35. For example, the processor 23 outputs the candidates whose calculated priority is higher than a specified threshold and that are in the top nth place (n is any natural number) in a manner that allows the user to grasp them preferentially.

### [Step S14]

Next, the processing proceeds to Step S14, where the acquisition unit 231 acquires the selection of the test conditions made by the user in Step S13.

### [Step S15]

Next, the processing proceeds to Step S15, where the processor 23 sets test conditions for each constant temperature bath 41 and the reference constant temperature bath 42 based on the acquired selection of the test conditions. The processor 23 in the present embodiment sets a reference test condition for the reference constant temperature bath 42. The reference test condition is common to the first deterioration test and the second deterioration test, and is set so that the deterioration test is performed under the same test condition on the secondary battery B housed in the reference constant temperature bath 42. The reference test condition in the present embodiment is the same as the initial test condition performed on the secondary battery B housed in the reference constant temperature bath 42 in Step S3. In other words, at least one of the test conditions is a reference test condition that is set regardless of the candidate of the test condition selected by the user.

### [Step S16]

Next, the processing proceeds to Step S16, where the processor 23, functioning as the replacement determination unit 237, determines whether or not the secondary battery B housed in the constant temperature bath 41 or the reference constant temperature bath 42 needs to be replaced. For example, the processor 23 determines that the replacement of the secondary battery B is necessary when the ratio (C_deg_total/C_ini) of the sum C_deg_total (so called total deterioration amount) of the capacity deterioration amount ΔC by the past deterioration tests to the initial capacity C_ini is greater than or equal to a default value. On the other hand, the processor 23 determines that the replacement of the secondary battery B is unnecessary when C_deg_total/C_ini is less than the default value. The default value can be set arbitrarily. In this manner, the processor 23, functioning as the replacement determination unit 237, determines, based on the acquired capacity deterioration amount ΔC, whether or not to replace the secondary battery B on which the deterioration test is performed.

### [Step S17]

In the case where it is determined that at least one secondary battery B needs to be replaced, the processing proceeds to Step S17, and the replacement determination unit 237 presents the secondary battery B that needs to be replaced to the user via the display unit 34 and requests the user to replace the secondary battery B. In the case where the secondary battery B is then replaced by the user, the processing proceeds to Step S18.

### [Step S18]

In Step S18, the processor 23 measures the initial capacity C_ini of the secondary battery B after replacement. The method of measuring the initial capacity C_ini is arbitrary, but is, for example, similar to the method described in Step S1. The processing then proceeds to Step S19. In the case where it is determined that the replacement of any of the secondary batteries B is not necessary, the processing of Steps S17 and S18 is omitted and the processing proceeds to Step S19.

### [Step S19]

In Step S19, the processor 23 executes a second deterioration test on each secondary battery B based on the test condition set in Step S15.

### [Step S20]

Next, the processing proceeds to Step S20, where the processor 23 measures the capacity deterioration amount ΔC of each secondary battery B in the second deterioration test. The test results including the measurement results are stored in the storage unit 22, etc., together with the corresponding second test conditions. The processor 23, functioning as the acquisition unit 231, acquires the test conditions of the first deterioration test performed on the secondary battery B and the test results from the first deterioration test by referring to the storage unit 22 and the like. The test results include the capacity deterioration amount ΔC of the secondary battery B.

### [Step S21]

Next, the processing proceeds to Step S21, and the processor 23, functioning as the rate calculation unit 232, calculates the capacity deterioration rate V of the secondary battery B under the test condition based on the capacity deterioration amount ΔC. For example, the processor 23 calculates the capacity deterioration rate V based on the test time ΔT of the second deterioration test that has been performed immediately before, the capacity deterioration amount ΔC by the second deterioration test, and the cumulative capacity deterioration amount ΔC_T, which is the cumulative total of the capacity deterioration amount ΔC up to the time immediately before the second deterioration test was performed. In the present embodiment, the processor 23 further calculates the cumulative test time T_s, which is the cumulative test time of the first deterioration test that has been performed in the past on the secondary battery B. The cumulative test time T_s is defined as, for example, a time until the capacity deterioration amount ΔC of a new secondary battery B that has been not subjected to a deterioration test reaches the cumulative capacity deterioration amount ΔC_T. The cumulative capacity deterioration amount ΔC_T and the cumulative test time T_s are one aspect of the history of the first deterioration test. Thus, it can be said that the processor 23, functioning as the rate calculation unit 232, further calculates the capacity deterioration rate V based on the history. For example, the processor 23 calculates the capacity deterioration rate V and the cumulative test time T_s based on the time dependence of the battery capacity C and its first-order variation as follows.

$$Δ {C}_{T} = V \times {T}_{s}^{a} \qquad [ Equation 1 ]$$

$$Δ {C}_{T} + Δ C = V \times {( {T}_{s} + Δ T )}^{a} \qquad [ Equation 2 ]$$

a is the order of time dependence of the cumulative capacity deterioration amount ΔC_T on the capacity deterioration rate V. From these conditional equations, the capacity deterioration rate V and the cumulative test time T_s can be obtained as follows.

$${T}_{s} = \frac{Δ {C}_{T}^{1 / a} \times Δ T}{{( Δ {C}_{T} + Δ C )}^{1 / a} - Δ {C}_{T}^{1 / a}} \qquad [ Equation 3 ]$$

$$V = \frac{Δ C}{{( {T}_{s} + Δ T )}^{a} - {T}_{s}^{a}} \qquad [ Equation 4 ]$$

In the present embodiment, the initial value of a is set to 0.5.

### [Step S22]

Next, the processing proceeds to Step S22, where the processor 23, functioning as the estimation unit 233, estimates the capacity deterioration rate V of the secondary battery B under the test condition of the second deterioration test based on the calculated capacity deterioration rate V. As mentioned above, the test condition to be set is an untested condition. Thus, the processor 23, functioning as the estimation unit 233, estimates, based on the calculated capacity deterioration rate V, the capacity deterioration rate V of the secondary battery B under at least one of the untested conditions representing the test conditions that have not been acquired. The measured capacity deterioration amount ΔC, the calculated capacity deterioration rate V, and the estimated capacity deterioration rate V are stored as test results in the storage unit 22 or the like in association with the respective test conditions.

### [Step S23]

Next, the processing proceeds to Step S23, where the processor 23 determines, by referring to the storage unit 22 or the like, whether or not there are test results of the first deterioration test other than the deterioration test performed in Step S3 as past test results. In other words, the processor 23 determines whether or not the processing of Step S19 has been performed in the past in a series of information processing.

### [Step S24]

In the case where it is determined that there is a test result of the first deterioration test other than the deterioration test performed in Step S3, the processing proceeds to Step S24, where the processor 23, functioning as the correction unit 238, executes correction processing for the estimation results of the capacity deterioration rate V in Step S22. As a result, the processor 23, functioning as the correction unit 238, corrects the calculated capacity deterioration rate V of the secondary battery B based on the capacity deterioration amount ΔC of the secondary battery B from the first deterioration test under the reference test condition, and outputs the corrected capacity deterioration rate V. The processor 23, for example, updates the order a through the correction processing and corrects the calculated or estimated capacity deterioration rate V so as to indicate the time dependence represented by the updated order a. Details of this correction processing will be described below. The processing then proceeds to Step S25. In the case where it is determined there is no test result of the first deterioration test other than the deterioration test performed in Step S3, the processing of Step S24 is omitted and the processing proceeds to Step S25.

### [Step S25]

Next, the processing proceeds to Step S25, where the processor 23, functioning as the map generation unit 239, generates a deterioration rate map M based on the calculated capacity deterioration rate V and the estimated capacity deterioration rate V. In the present embodiment, since the deterioration rate map M has already been generated in Step S7, the processor 23 updates the existing deterioration rate map M with the newly generated deterioration rate map M.

### [Step S26]

Next, the processing proceeds to Step S26, where the processor 23 determines whether or not a predetermined number or more of past test results have been accumulated. The past test results and the predetermined number are the same as those used in the determination in Step S9.

### [Step S27]

In the case where it is determined that a predetermined number or more of past test results have been accumulated, the processing proceeds to Step S27, where the measurement error of the capacity deterioration amount ΔC under the untested condition is determined, and the untested condition with a relatively large measurement error is extracted. The specific aspect of this processing is arbitrary, but for example, the processor 23 estimates the measurement error of the capacity deterioration amount ΔC under the untested condition based on the deterioration rate map using a method similar to that of Step S10, classifies the untested conditions into the first classification and the second classification according to the estimation result as the classification unit 240, and extracts the untested condition classified into the first classification as an untested condition with a relatively large measurement error. When making such a classification, the processor 23 performs the classification based at least on the condition (2) described above. Therefore, the classification reflects the reliability of the deterioration rate map.

### [Step S28]

Next, the processing proceeds to Step S28, where the processor 23 estimates the capacity deterioration rate V under the untested conditions belonging to the first classification based on the reliability of the above deterioration rate map M and the above measurement error, and updates the deterioration rate map M based on the estimation result. For example, the processor 23 adds the capacity deterioration rate V which is estimated based on the existing deterioration rate map M as training data for the deterioration rate map M. As a result, the processor 23 updates the trained model that represents the physical model of the secondary battery B. Then, the processor 23 re-generates the deterioration rate map M based on the updated trained model, and updates the existing deterioration rate map M. In this manner, it is possible to further improve the accuracy of the deterioration rate map M by adding an estimated value of the capacity deterioration rate V with a certain level of accuracy guaranteed as training data. In other words, the processor 23, functioning as the estimation unit 233, estimates the capacity deterioration rate V of the secondary battery B under the untested conditions based on the deterioration rate map M. Also, the processor 23, functioning as the classification unit 240, classifies the untested conditions into the first classification and the second classification based on the estimated capacity deterioration rate V of the secondary battery B. Here, the first classification is a classification that indicates an untested condition in which the error in the capacity deterioration rate V is larger than that in the untested condition belonging to the second classification. The processor 23, functioning as the map generation unit 239, updates the deterioration rate map M based on the reliability of the deterioration rate map M and the capacity deterioration rate V estimated for at least the untested condition belonging to the first classification.

According to this configuration, it is possible to update the deterioration rate map M using the estimation result of the capacity deterioration rate V for the untested condition where the error in the capacity deterioration rate V is relatively large. Thus, the accuracy of the deterioration rate map M can be further improved. In the present embodiment, the processor 23 actually allows a deterioration test to be performed particularly within a range of the test condition in which the measurement error of the capacity deterioration rate V is relatively small, and for the test condition in which the measurement error is relatively large, the processor 23 adds training data corresponding to the test condition using an estimation result of the capacity deterioration rate V that is more reliable than the case where an actual test is performed. The processor 23 updates the deterioration rate map M using the newly added training data based on such a test result and an estimation result. This can further improve the accuracy of the deterioration rate map.

Here, an example of processing of extracting test conditions for estimating the capacity deterioration rate V from among the test conditions belonging to the first classification will be described. First, the processor 23 sets the number of test conditions to be extracted. The number of test conditions to be extracted is arbitrary, for example, as long as it is less than the total number of test conditions of the deterioration tests that have been performed so far. Next, the test condition that maximizes one of the parameters that define the priority (in the present embodiment, the standard deviation of the capacity deterioration rate V) is selected. Next, the processor 23 acquires the capacity deterioration rate V under the selected test conditions based on the latest deterioration rate map M as a virtual capacity deterioration rate V. Next, the processor 23 adds the acquired virtual capacity deterioration rate V_m to the training data and updates the standard deviation of the capacity deterioration rate V. This may result in a smaller standard deviation of the capacity deterioration rate V around the selected test conditions. Thereafter, the processor 23 selects the test condition that maximizes the standard deviation of the capacity deterioration rate V again in the updated state, and repeats the above processing until the number of selected test conditions reaches the number of test conditions to be extracted. In this way, the accuracy of the deterioration rate map M can be improved while reducing the cost of the deterioration test by reflecting the test conditions under which no deterioration test has been actually performed in the deterioration rate map M.

### [Step S29]

Next, the processing proceeds to Step S29, where the processor 23 determines whether or not the termination condition has been achieved. The termination condition is arbitrary, but for example, the processor 23 determines that the termination condition is satisfied when the average value of the standard deviations of the capacity deterioration rate V under all test conditions within the search range based on the latest deterioration rate map M becomes less than or equal to a predetermined percentage of the average value of the standard deviations of the capacity deterioration rate V in the initial deterioration rate map M. The predetermined percentage can be set arbitrarily, for example, to 1%, 5%, 10%, etc.

In the case where it is determined that the termination condition is satisfied, the information processing system 1 outputs the latest deterioration rate map M as the final result and terminates this information processing.

On the other hand, in the case where it is determined that the termination condition is not satisfied, the processing returns to Step S8, and the above-mentioned processing is repeated to further perform a second deterioration test and update the deterioration rate map M. In this cycle, the processor 23 treats the second deterioration test performed in the most recent Step S19 as the first deterioration test. By repeating such information processing, the test results of the first deterioration test, etc. are accumulated in the storage unit 22, etc.

### 3.2. Details of Search Processing

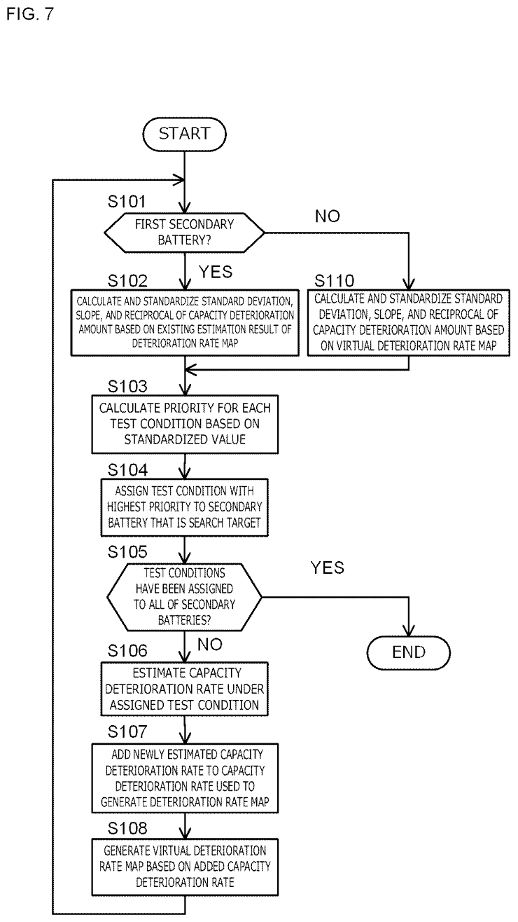

This section describes the details of the search processing in Step S12. FIG. 7 is a flowchart showing a flow of the search processing.

### [Step S101]

First, in Step S101, the processor 23 determines whether or not the search target for the candidates of the test condition is the first secondary battery B. When the search target is the first secondary battery B, the virtual capacity deterioration rate V_m described below has not been generated. Thus, the processor 23 may determine whether or not the virtual capacity deterioration rate V_m has been generated. In the case where it is determined that the search target for the candidates of the test condition is the first secondary battery B, the processing proceeds to Step S102. On the other hand, in the case where it is determined that the search target for the candidates of the test condition is not the first secondary battery B, in other words, in the case where it is determined that the search target is the second or subsequent secondary battery B, the processing proceeds to Step S110.

### [Step S102]

Here, a case will be described in which it is determined that the search target for the candidates of the test condition is the first secondary battery B along time series and the processing proceeds to Step S102. In Step S102, the processor 23 calculates and standardizes the standard deviation, slope, and reciprocal of the capacity deterioration rate V for each test condition based on the existing estimation result of the capacity deterioration rate V. The specific aspects of the above processing are as described above.

### [Step S103]

Next, the processing proceeds to Step S103, where the processor 23 calculates priority for each test condition based on the standardized values. As the priority, the one set in Step S11 is used.

### [Step S104]

Next, the processing proceeds to Step S104, where the processor 23 assigns the test condition with the highest priority to the secondary battery B that is the search target. The number of candidates of the test condition to be assigned is not limited to one, but may be multiple.

### [Step S105]

Next, the processing proceeds to Step S105, where the processor 23 determines whether or not the test conditions have been assigned to all of the secondary batteries B.

### [Step S106]

In the case where it is determined that the test conditions have not been assigned to all of the secondary batteries B, the processing proceeds to Step S106, where the capacity deterioration rate V under the assigned test condition is estimated based on the latest deterioration rate map M.

### [Step S107]

Next, the processing proceeds to Step S107, where the processor 23 adds the newly estimated capacity deterioration rate V as the training data to the capacity deterioration rate V used to generate the deterioration rate map M.

### [Step S108]

Next, the processing proceeds to Step S108, where the processor 23 generates a virtual deterioration rate map M based on the added capacity deterioration rate V. This allows the optimal test conditions to be assigned to the other secondary batteries B in the case where the assigned deterioration test is performed. The processor 23 may update the virtual deterioration rate map M as the latest deterioration rate map M. The processing then returns to Step S101 to determine whether or not the search target is the first secondary battery B.

### [Step S110]

In the case where the processing of Step S101 is executed via Step S108, the determination result is negative, and the processing proceeds to Step S110 as described above. In Step S110, the processor 23 calculates and standardizes the standard deviation, slope, and reciprocal of the capacity deterioration rate V based on the virtual deterioration rate map M generated in Step S108. The above processing is the same as those in Step S102. Then, each of the processing of Step S103 to Step S105 is performed. In the case where it is determined in Step S105 that the test conditions have been assigned to all of the secondary batteries B, the processing of Step S12 is terminated, the assigned test conditions are output as search results, and the processing proceeds to Step S13.

3.3. Details of the correction processing

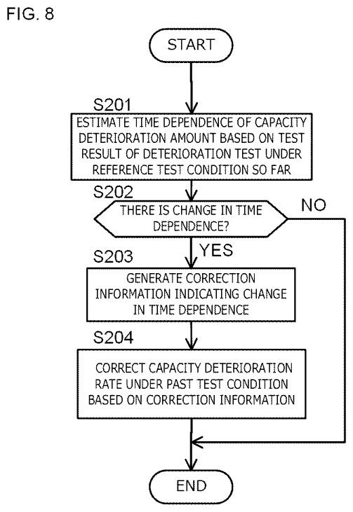

This section describes the details of the correction processing executed in Step S24. FIG. 8 is a flowchart showing a flow of the correction processing.

### [Step S201]

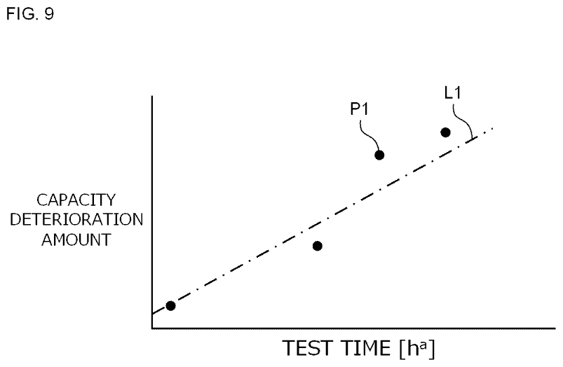

First, in Step S201, the processor 23 estimates the time dependence of the capacity deterioration amount ΔC based on the test results of the deterioration tests under the reference test conditions so far. The estimation of the time dependence is performed, for example, by optimizing the order a based on the least-squares method, etc., for the data set expressed by the capacity deterioration amount ΔC and the cumulative test time T_s. FIG. 9 shows an example of the estimation results of the time dependence of the capacity deterioration amount ΔC. As shown in FIG. 9, the test results of the deterioration test under the reference test condition is represented as points P1. For such a plurality of points P1, the time dependence of the capacity deterioration amount ΔC when the order a of the test time is changed from 0.5 in a predetermined step width is expressed as a function L1. The processor 23 estimates that the order a in which the error between the function L1 and the points P1 becomes minimum is the order that represents the latest time dependence.

### [Step S202]

Returning to FIG. 8, the processing then proceeds to Step S202, where the processor 23 determines whether there is a change in time dependence by comparing the order a estimated in Step S201 with the most recent order a (the default setting is 0.5). For example, in the case where the absolute value of the difference between the order a estimated in Step S201 and the most recent order a is within the allowable value, the processor 23 determines that there is no change in time dependence, and the processing proceeds to Step S203.

### [Step S203]

In Step S203, the processor 23 generates correction information indicating a change in time dependence. The correction information can also be thought of as an instruction to change the order a and correct the capacity deterioration rate V associated with this change in Step S204 described below. The processor 23 may not constantly update the order a from the initial value (0.5 in the present embodiment), but may temporarily change the order a when it is determined in step S202 that there is a change in the time dependence.

### [Step S204]

The processing then proceeds to Step S204, where the processor 23 corrects, based on the generated correction information, the capacity deterioration rate V under the test condition that has been performed in the past, thereby ensuring consistency with the time dependence defined by the order a estimated in Step S201. This allows the time dependence due to the type of secondary battery B to be reflected in the deterioration rate map M. Then, the correction processing of Step S24 ends.

In addition, in Step S202, in the case where the absolute value of the difference between the order a estimated in Step S201 and the most recent order a is within the allowable value, the processing of Step S203 and Step S204 is omitted, and the processor 23 terminates the correction processing of Step S24 without making any correction.

### 4. Others

The above-described aspects of the information processing are solely examples, and the present disclosure is not limited to those.

The processor 23 may calculate the capacity deterioration amount ΔC based on the impedance and the open circuit voltage of the secondary battery B. These values are measured by the charge and discharge device 43 or the impedance measurement device 44. For example, the processor 23 calculates the capacity deterioration amount ΔC from the impedance and the open circuit voltage by referring to a previously constructed correspondence relation of the battery capacity C relative to the impedance and the open circuit voltage of the secondary battery B. The correspondence relation is represented, for example, by a trained model constructed in advance according to an arbitrary learning algorithm such as random forest or a support vector machine, or a data table measured in advance, etc.

In Step S13, the processor 23, functioning as the candidate output unit 236, further outputs candidates for the second deterioration test based on the transition time t12. The transition time t12 is the time required for transition from the first deterioration test to the second deterioration test, and is one of the indices representing the cost of performing the second deterioration test. In this case, the transition time t12 is one of the parameters that defines the priority. In this case, the priority is further defined, for example, by a weighted linear sum of the reciprocal of the transition time t12, in addition to the standard deviation of the capacity deterioration rate V, the slope of the capacity deterioration rate V, and the reciprocal of the capacity deterioration rate V, as described above. The reciprocal of the transition time t12 becomes larger as the time from the first deterioration test to the second deterioration test becomes shorter. Therefore, the shorter the transition time t12 under the test condition, the greater the priority becomes.

In this case, for example, in Step S11, the processor 23, functioning as the priority calculation unit 235, further calculates the transition time t12 based on the test condition of the first deterioration test and the test condition of the second deterioration test. For example, the processor 23 calculates the transition time t12 by dividing the difference between the temperature under the test condition of the first deterioration test and the temperature under the test condition of the second deterioration test by the upper limit of the heating rate of the constant temperature bath 41. The processor 23 may also calculate the transition time t12 based on the average SOC or SOC range included in the test conditions. For example, the processor 23 compares the SOC of the secondary battery B after the end of the first deterioration test with the SOC at the start of the second deterioration test, and calculates the transition time t12 based on the current rate at which the secondary battery B is charged. The processor 23 may adopt the maximum value of these respective transition times t12 or the sum of these transition times t12 as the transition time t12 to be used as a parameter of priority.

The processor 23 further calculates the priority corresponding to the test condition of the second deterioration test further based on the transition time t12 calculated in this manner, and searches for candidates for the test condition of the second deterioration test based on the calculated priority in Step S12.

The priority need not be defined by a linear sum of the above-mentioned parameters, but may be defined by any function or table, for example, non-linear coupling, etc. of each of the above-mentioned parameters. For example, the priority may be defined by a linear sum of squares of the above-mentioned parameters.

The method of determining whether or not the secondary battery B needs to be replaced is not limited to the above-mentioned method and may be any method. For example, the processor 23 may calculate the state of health (SOH) of the secondary battery B based on the total C_deg_total of the capacity deterioration amount ΔC and the internal resistance of the secondary battery B, and make the determination based on whether the SOH is equal to or greater than a default value. The internal resistance of the secondary battery B can be calculated, for example, by comparing the closed circuit voltage with the open circuit voltage measured by the charge and discharge device 43 or the impedance measurement device 44 when a certain current flows through the secondary battery B. In addition to the acquired capacity deterioration amount ΔC, the processor 23 may further determine whether or not to replace the secondary battery B based on the selected test condition of the second deterioration test. For example, the processor 23 may change the default value to be compared with C_deg_total/C_ini depending on the load of the predetermined test conditions.

The deterioration testing apparatus 4 may have any configuration as long as it is possible to measure the capacity deterioration amount ΔC. Also, the charge and discharge device 43 and the impedance measurement device 44 may be integrated. The deterioration testing apparatus 4 does not have to include the impedance measurement device 44. The measurement function of the capacity deterioration amount ΔC included in the deterioration testing apparatus 4 may be realized by other devices such as the information processing apparatus 2. In other words, the distinction between the information processing apparatus 2, the user terminal 3, and the deterioration testing apparatus 4 is merely for convenience of explanation, and is not limited thereto.

The information processing apparatus 2 may be an on-premises system or a cloud-based system. As a cloud-based information processing system 1, the above-mentioned functions and processing may be provided, for example, in the form of Saas (Software as a Service) or cloud computing.

In the above-described embodiment, the information processing apparatus 2 executes various storage and control operations, but a plurality of external devices may be used instead of the information processing apparatus 2. In other words, various kinds of information and programs may be divided to be stored into the plurality of the external devices by using blockchain technology or the like.

The above-mentioned embodiment is not limited to the information processing system 1, and may be an information processing method or an information processing program. The information processing method includes each of the steps of the information processing system 1. The information processing program allows at least one computer to execute each of the steps of the information processing system 1.

The above-described information processing system 1 and the like may be provided in each of following aspects.

(1) An information processing system, comprising at least one processor configured to execute a program so as to execute each step of: an acquisition step of acquiring a test condition of a first deterioration test performed on a secondary battery and a test result from the first deterioration test, the test condition including a test time for performing the first deterioration test, the test result including a capacity deterioration amount of the secondary battery; a rate calculation step of calculating a capacity deterioration rate of the secondary battery under the test condition based on the capacity deterioration amount; an estimation step of estimating, based on the calculated capacity deterioration rate, a capacity deterioration rate of the secondary battery under at least one of untested conditions representing test conditions that have not been acquired; a map generation step of generating a deterioration rate map that indicates a correspondence relation between the test condition and the capacity deterioration rate based on the calculated capacity deterioration rate and the estimated capacity deterioration rate; a priority calculation step of calculating, based on the generated deterioration rate map, priority of each of the untested conditions for performing a second deterioration test; and a candidate output step of outputting, based on the calculated priority, a candidate for the second deterioration test in which at least one of the untested conditions is a test condition, in a manner selectable by a user.

According to this configuration, the conditions for the deterioration test that should be performed next can be selected more efficiently from among the untested conditions. Thus, the accuracy of the deterioration rate map can be improved more efficiently.

(2) The information processing system according to (1), wherein: the priority calculation step includes calculating the priority based on at least one of reliability of the deterioration rate map obtained by further performing a second deterioration test on the secondary battery under at least one of the untested conditions and a cost of performing the second deterioration test.

According to this configuration, the interpretability of the significance of the conditions for the deterioration test that should be performed next can be improved.

(3) The information processing system according to (1) or (2), wherein: the acquisition step further includes acquiring a history of the first deterioration test performed on the secondary battery, and the rate calculation step further includes calculating the capacity deterioration rate based on the history.

According to this configuration, a deterioration rate map can be generated using a secondary battery that has been subjected to the deterioration test in the past and has been deteriorated, thereby reducing the cost of performing deterioration tests.

(4) The information processing system according to any one of (1) to (3), wherein: the acquisition step includes acquiring test conditions of a plurality of first deterioration tests performed on each of a plurality of secondary batteries and a capacity deterioration amount of each of the secondary batteries obtained from each of the plurality of first deterioration tests, at least one of the test conditions is a reference test condition that is set regardless of a candidate of a test condition selected by a user, and the at least one processor is configured to execute a program so as to execute a correction step of correcting the calculated capacity deterioration rate of the secondary battery based on the capacity deterioration amount of the secondary battery by the first deterioration test under the reference test condition.

According to this configuration, the accuracy of the deterioration rate map can be further improved by correcting the deterioration rate calculation results obtained from a short-term deterioration test based on information obtained from a long-term deterioration test under the same test conditions.

(5) The information processing system according to any one of (1) to (4), wherein: the at least one processor is configured to execute a program so as to execute a replacement determination step of determining, based on the acquired capacity deterioration amount, whether or not to replace the secondary battery on which the second deterioration test is performed.

According to this configuration, it becomes easier to perform a deterioration test under an appropriate load on the secondary battery.

(6) The information processing system according to any one of (1) to (5), wherein: reliability of the deterioration rate map is calculated based on at least one of statistics of the estimated capacity deterioration rate and a slope of the calculated capacity deterioration rate with respect to parameters related to the test condition of the deterioration rate map.

According to this configuration, a more accurate deterioration rate map can be obtained.

(7) The information processing system according to any one of (1) to (6), wherein: the priority calculation step further includes calculating a transition time that is required for transition from the first deterioration test to the second deterioration test based on the test condition of the first deterioration test and a test condition of the second deterioration test, and the candidate output step further includes outputting a candidate for the second deterioration test based on the transition time.

According to this configuration, the deterioration test can be performed efficiently while taking into consideration the time required for the entire deterioration test.

(8) The information processing system according to any one of (1) to (7), wherein: the acquisition step further includes acquiring reliability of the generated deterioration rate map, the estimation step includes estimating a capacity deterioration rate of the secondary battery under the untested conditions based on the deterioration rate map, the at least one processor is configured to execute a program so as to further execute a classification step of classifying the untested conditions into a first classification and a second classification based on the estimated capacity deterioration rate of the secondary battery, the first classification is a classification that indicates an untested condition in which an error in a capacity deterioration rate is larger than that in an untested condition belonging to the second classification, and the map generation step includes updating the deterioration rate map based on the reliability of the deterioration rate map and the capacity deterioration rate estimated for at least an untested condition belonging to the first classification.

According to this configuration, the deterioration rate map can be updated by using the estimation results of the capacity deterioration rate for the untested conditions in which the error in the capacity deterioration rate is relatively large, thereby further improving the accuracy of the deterioration rate map.

(9) The information processing system according to any one of (1) to (8), wherein: the at least one processor is configured to execute a program so as to further execute a priority setting step of setting a priority correspondence relation based on designation by a user, the priority correspondence relation indicates at least a correspondence relation of the priority to reliability of the deterioration rate map by further performing the second deterioration test on the secondary battery and a cost of performing the second deterioration test, and the priority calculation step further includes calculating the priority based on the set priority correspondence relation.

According to this configuration, it is possible to output suitable candidates for the second deterioration test in accordance with the elements considered important by the user.

(10) An information processing method, comprising each of the steps of the information processing system according to any one of (1) to (9).

(11) An information processing program, configured to allow at least one computer to execute each of the steps of the information processing system according to any one of (1) to (9).

Of course, the present disclosure is not limited to the above aspects.

Finally, various embodiments of the present disclosure have been described, but these are presented as examples and are not intended to limit the scope of the invention. Novel embodiments can be implemented in various other forms, and various omissions, replacements, and modifications can be made within the scope of the spirit of the invention. The embodiments and its modifications are included in the scope and the spirit of the invention and are included in the scope of the invention described in claims and the equivalent scope thereof.

### REFERENCE SIGNS LIST

1: Information processing system
2: Information processing apparatus
20: Communication bus
21: Communication unit
22: Storage unit
23: Processor
231: Acquisition unit
232: Rate calculation unit
233: Estimation unit
234: Priority setting unit
235: Priority calculation unit
236: Candidate output unit
237: Replacement determination unit
238: Correction unit
239: Map generation unit
3: User terminal
30: Communication bus
31: Communication unit
32: Storage unit
33: Processor
34: Display unit
35: HMI device
4: Deterioration testing apparatus
41: Constant temperature bath
42: Reference constant temperature bath
43: Charge and discharge device
44: Impedance measurement device
B: Secondary battery
L1: Function
P1: Point

1. An information processing system, comprising at least one processor configured to execute a program so as to execute each step of:
an acquisition step of acquiring a test condition of a first deterioration test performed on a secondary battery and a test result from the first deterioration test, the test condition including a test time for performing the first deterioration test,
the test result including a capacity deterioration amount of the secondary battery;
a rate calculation step of calculating a capacity deterioration rate of the secondary battery under the test condition based on the capacity deterioration amount;
an estimation step of estimating, based on the calculated capacity deterioration rate, a capacity deterioration rate of the secondary battery under at least one of untested conditions representing test conditions that have not been acquired;
a map generation step of generating a deterioration rate map that indicates a correspondence relation between the test condition and the capacity deterioration rate based on the calculated capacity deterioration rate and the estimated capacity deterioration rate;
a priority calculation step of calculating, based on the generated deterioration rate map, priority of each of the untested conditions for performing a second deterioration test; and
a candidate output step of outputting, based on the calculated priority, a candidate for the second deterioration test in which at least one of the untested conditions is a test condition, in a manner selectable by a user.

2. The information processing system according to claim 1, wherein:
the priority calculation step includes calculating the priority based on at least one of reliability of the deterioration rate map obtained by further performing a second deterioration test on the secondary battery under at least one of the untested conditions and a cost of performing the second deterioration test.

3. The information processing system according to claim 1, wherein:
the acquisition step further includes acquiring a history of the first deterioration test performed on the secondary battery, and
the rate calculation step further includes calculating the capacity deterioration rate based on the history.

4. The information processing system according to claim 1, wherein:
the acquisition step includes acquiring test conditions of a plurality of first deterioration tests performed on each of a plurality of secondary batteries and a capacity deterioration amount of each of the secondary batteries obtained from each of the plurality of first deterioration tests, at least one of the test conditions is a reference test condition that is set regardless of a candidate of a test condition selected by a user, and
the at least one processor is configured to execute a program so as to execute a correction step of correcting the calculated capacity deterioration rate of the secondary battery based on the capacity deterioration amount of the secondary battery by the first deterioration test under the reference test condition.

5. The information processing system according to claim 1, wherein:
the at least one processor is configured to execute a program so as to execute a replacement determination step of determining, based on the acquired capacity deterioration amount, whether or not to replace the secondary battery on which the second deterioration test is performed.

6. The information processing system according to claim 1, wherein:
reliability of the deterioration rate map is calculated based on at least one of statistics of the estimated capacity deterioration rate and a slope of the calculated capacity deterioration rate with respect to parameters related to the test condition of the deterioration rate map.

7. The information processing system according to claim 1, wherein:
the priority calculation step further includes calculating a transition time that is required for transition from the first deterioration test to the second deterioration test based on the test condition of the first deterioration test and a test condition of the second deterioration test, and
the candidate output step further includes outputting a candidate for the second deterioration test based on the transition time.

8. The information processing system according to claim 1, wherein:
the acquisition step further includes acquiring reliability of the generated deterioration rate map,
the estimation step includes estimating a capacity deterioration rate of the secondary battery under the untested conditions based on the deterioration rate map,
the at least one processor is configured to execute a program so as to further execute a classification step of classifying the untested conditions into a first classification and a second classification based on the estimated capacity deterioration rate of the secondary battery, the first classification is a classification that indicates an untested condition in which an error in a capacity deterioration rate is larger than that in an untested condition belonging to the second classification, and
the map generation step includes updating the deterioration rate map based on the reliability of the deterioration rate map and the capacity deterioration rate estimated for at least an untested condition belonging to the first classification

9. The information processing system according to claim 1, wherein:
the at least one processor is configured to execute a program so as to further execute a priority setting step of setting a priority correspondence relation based on designation by a user, the priority correspondence relation indicates at least a correspondence relation of the priority to reliability of the deterioration rate map by further performing the second deterioration test on the secondary battery and a cost of performing the second deterioration test, and
the priority calculation step further includes calculating the priority based on the set priority correspondence relation.

10. An information processing method,
comprising each of the steps of the information processing system according to claim 1.

11. A non-transitory computer-readable storage medium storing an information processing program, configured to allow at least one computer to execute each of the steps of the information processing system according to claim 1.
